(19) United States
(12) Patent Application Publication
(10) Pub. No.: US 2018/0358221 A1
(43) Pub. Date: Dec. 13, 2018

(54) REDUCTION OF WAFER BOW DURING GROWTH OF EPITAXIAL FILMS

(71) Applicant: MACOM Technology Solutions Holdings, Inc., Lowell, MA (US)

(72) Inventors: Douglas Carlson, Lowell, MA (US); Timothy E. Boles, Tyngsboro, MA (US)

(73) Assignee: MACOM Technology Solutions Holdings, Inc., Lowell, MA (US)

(21) Appl. No.: 15/616,699

(22) Filed: Jun. 7, 2017

(51) Int. Cl. H01L 21/02; H01L 29/20; H01L 33/00; H01L 33/32; C30B 29/40; C30B 25/18; H01S 5/24; H01S 5/02; H01S 5/323

(52) U.S. Cl. CPC H01L 21/0243; H01S 2301/173; H01L 21/02378; H01L 21/0242; H01L 21/02499; H01L 21/0254; H01L 29/2003; H01L 33/007; H01L 33/32; C30B 29/406; C30B 25/183; H01S 5/24; H01S 5/0206; H01S 5/32341; H01S 5/0205; H01L 21/02381

(57) ABSTRACT

Structures and methods for reducing wafer bow during heteroepitaxial growth are described. Micro-trenches may be formed across a surface of a substrate and filled with polycrystalline material. Stress-relieving regions of material can be grown over the polycrystalline material in a layer of semiconductor material during heteroepitaxy.

### BACKGROUND

### Technical Field

The technology relates to epitaxial growth of crystalline layers on semiconductor wafers.

### Discussion of the Related Art

Gallium-nitride semiconductor material has received appreciable attention in recent years because of its desirable electronic and electro-optical properties. Gallium nitride (GaN) has a wide, direct bandgap of about 3.4 eV that corresponds to the blue wavelength region of the visible spectrum. Light-emitting diodes (LEDs) and laser diodes (LDs) based on GaN and its alloys have been developed and are commercially available. These devices can emit visible light ranging from the violet to red regions of the visible spectrum.

Because of its wide bandgap, gallium nitride is more resistant to avalanche breakdown and has a higher intrinsic field strength compared to more common semiconductor materials, such as silicon and gallium arsenide. In addition, gallium nitride is a wide bandgap semiconductor and is able to maintain its electrical performance at higher temperatures as compared to other semiconductors, such as silicon or gallium arsenide. GaN also has a higher carrier saturation velocity compared to silicon. Additionally, GaN has a Wurtzite crystal structure, is a hard material, has a high thermal conductivity, and has a much higher melting point than other conventional semiconductors such as silicon, germanium, and gallium arsenide. Accordingly, GaN is useful for high-speed, high-voltage, and high-power applications. For example, gallium-nitride materials are useful in semiconductor amplifiers for radio-frequency (RF) communications, radar, and microwave applications.

Although GaN is a desirable semiconductor material for many applications, it is more expensive to produce than conventional silicon semiconductor wafers. One approach to producing GaN for semiconductor device manufacture is to epitaxially overgrow a layer of GaN on a wafer of a different material, such as silicon, silicon carbide, or sapphire. However, due to mismatches in material properties, such heteroepitaxy can lead to in-plane stresses in the GaN layer and cause out-of-plane wafer bending, as depicted by the bowed wafer 100 in FIG. 1. Wafer bow can lead to microfabrication problems during integrated circuit manufacture, and if severe enough can cause defects and cracks to form in an overgrown layer. In severe cases, the in-plane stresses may lead to layer delamination.

### SUMMARY

Structures and methods for reducing wafer bow in heteroepitaxy are described. In some embodiments, micro-trenches are formed across a surface of a substrate that is used for heteroepitaxial overgrowth. The trenches are filled with a material before overgrowth. Non-monocrystalline material may form in regions over the filled trenches and relieve in-plane stress in a heteroepitaxial layer during heteroepitaxial overgrowth. The relief of in-plane stresses can reduce wafer bow and reduce defects in device areas of the heteroepitaxial layer.

Some embodiments relate to a semiconductor wafer comprising a substrate formed of a first material, a layer of a second material different from the first material formed over the first material, a plurality of micro-trenches formed in a surface of the substrate that faces the layer of the second material, a third material different from the first material located in the micro-trenches, and a fourth material different from the second material located in regions above the third material in the layer of the second material that relieves in-plane stress in the layer of second material.

In some aspects, the second material may be a monocrystalline gallium-nitride material and the fourth material is polycrystalline or amorphous gallium-nitride material. In some implementations, a thickness of the second layer may be between 1 micron and 6 microns. In some cases, the plurality of micro-trenches are distributed across an entire surface of the substrate in a regular pattern that includes intersecting micro-trenches. In some aspects, the plurality of micro-trenches are distributed across an entire surface of the substrate in die streets. In some implementations, device areas are located in regions between the plurality micro-trenches and span a distance between 0.5 mm and 10 mm. In some cases, the micro-trenches have a cross-sectional profile with non-vertical sidewalls. In some aspects, the micro-trenches have a width between 1 micron and 100 microns. According to some implementations, the substrate comprises silicon, silicon-carbide, or sapphire.

According to some aspects, a semiconductor wafer may further comprise a buffer formed between the substrate and the layer of the second material. In some cases, a semiconductor wafer may further comprise integrated circuit devices formed in device areas that are located between the plurality of micro-trenches.

Some embodiments relate to a semiconductor die comprising a substrate formed of a first material, a layer of a second material different from the first material formed over the first material, an integrated circuit device formed in the layer of the second material, a micro-trench or portion thereof formed in a surface of the substrate that faces the layer of the second material, a third material different from the first material located in the micro-trench or portion thereof, and a fourth material different from the second material located in a region above the third material in the layer of the second material that relieves in-plane stress in the layer of second material. In some implementations, a semiconductor die may further comprise a buffer formed between the substrate and the layer of the second material.

In some aspects, the second material may be a monocrystalline gallium-nitride material and the fourth material is polycrystalline or amorphous gallium-nitride material. In some cases, a thickness of the second layer is between 1 micron and 6 microns. In some implementations, the micro-trench or portion thereof may be located at a periphery of the die. In some cases, the substrate comprises silicon, silicon-carbide, or sapphire.

Some embodiments relate to methods for reducing bow during semiconductor heteroepitaxial growth. Such methods may comprise acts of forming a plurality of micro-trenches in a surface of a substrate comprising a first material; depositing a second material different from the first material over the substrate and the plurality of micro-trenches; performing a planarization process that removes a portion of the second material; epitaxially growing a layer of third material different from the first material over the substrate; and forming regions of fourth material different from the third material in the layer of third material over the micro-trenches, wherein the fourth material relieves in-plane stress in the layer of third material.

In some cases, the third material may be a monocrystalline gallium-nitride material and the fourth material may be a polycrystalline or amorphous gallium-nitride material. In some implementations, the third material and the fourth material are formed at a same time. According to some aspects, the layer of third material is grown to a thickness between 1 micron and 6 microns.

Some implementations of a method may further comprise forming the plurality of micro-trenches in die streets. In some cases, a method may comprise dicing the substrate along the micro-trenches to remove all or a portion of the micro-trenches. A method embodiment may further include forming a buffer between the substrate and the layer of third material. A method may further include forming an integrated circuit device in the layer of third material.

The foregoing apparatus and method embodiments may be implemented with any suitable combination of aspects, features, and acts described above or in further detail below. These and other aspects, embodiments, and features of the present teachings can be more fully understood from the following description in conjunction with the accompanying drawings.

### BRIEF DESCRIPTION OF THE DRAWINGS

The skilled artisan will understand that the figures, described herein, are for illustration purposes only. It is to be understood that in some instances various aspects of the embodiments may be shown exaggerated or enlarged to facilitate an understanding of the embodiments. The drawings are not necessarily to scale, emphasis instead being placed upon illustrating the principles of the teachings. In the drawings, like reference characters generally refer to like features, functionally similar and/or structurally similar elements throughout the various figures. Where the drawings relate to microfabricated circuits, only one device and/or circuit may be shown to simplify the drawings. In practice, a large number of devices or circuits may be fabricated in parallel across a large area of a substrate or entire substrate. Additionally, a depicted device or circuit may be integrated within a larger circuit.

When referring to the drawings in the following detailed description, spatial references “top,” “bottom,” “upper,” “lower,” “vertical,” “horizontal,” “above,” “below” and the like may be used. Such references are used for teaching purposes, and are not intended as absolute references for embodied devices. An embodied device may be oriented spatially in any suitable manner that may be different from the orientations shown in the drawings. The drawings are not intended to limit the scope of the present teachings in any way.

FIG. 1 depicts a bowed wafer;

FIG. 2 depicts a wafer having micro-trenches formed therein, according to some embodiments;

FIG. 3A illustrates a cross-section of a portion of a wafer having micro-trenches formed therein, according to some implementations;

FIG. 3B illustrates deposition of a fill material into the micro-trenches, according to some implementations;

FIG. 3C depicts a planarized wafer with filled micro-trenches, according to some implementations;

FIG. 4 depicts heteroepitaxy layers grown on a wafer with filled micro-trenches, according to some embodiments; and

FIG. 5 depicts a die with an integrated circuit, according to some embodiments.

Features and advantages of the illustrated embodiments will become more apparent from the detailed description set forth below when taken in conjunction with the drawings.

### DETAILED DESCRIPTION

Heteroepitaxy has become a useful process for forming high-performance or specialized semiconductor materials at reduced cost and large wafer sizes compared to forming bulk substrates of a desired semiconductor material. In heteroepitaxy, a desired monocrystalline semiconductor material is grown over a dissimilar crystalline material. The heteroepitaxy layer may be formed using a chemical vapor deposition process, for example, or any other suitable crystal-growth process. Some examples of heteroepitaxial systems include gallium-nitride materials grown on silicon, silicon-carbide, or sapphire substrates. There are many other heteroepitaxy systems, and the technology described herein is not limited to only gallium-nitride materials. Examples of other heteroepitaxy systems include, but are not limited to, any of silicon-carbide, silicon-germanium, gallium-arsenide materials, gallium-phosphide materials, and indium-phosphide materials grown on silicon or other substrate materials. In some implementations, heteroepitaxy may include forming a buffer (e.g., one or more transitional layers of different material and/or different alloys) between the substrate and a desired semiconductor material in which devices will be fabricated.

As used herein, the phrase “gallium-nitride material” refers to gallium nitride (GaN) and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₓP_{y}N_{(1-x-y)}), aluminum indium gallium arsenide phosphide nitride (AlₓIn_{y)}Ga_{(1-x-y)}AsₐP_{b}N_{(1-a-b)}), amongst others. Typically, when present, arsenic and/or phosphorous are at low concentrations (i.e., less than 5 percent by weight). In certain preferred embodiments, the gallium-nitride material has a high concentration of gallium and includes little or no amounts of aluminum and/or indium. In high gallium concentration embodiments, the sum of (x+y) may be less than 0.4 in some implementations, less than 0.2 in some implementations, less than 0.1 in some implementations, or even less in other implementations. In some cases, it is preferable for at least one gallium-nitride material layer to have a composition of GaN (i.e., x=y=a=b=0). For example, an active layer in which a majority of current conduction occurs may have a composition of GaN. Gallium-nitride materials may be doped n-type or p-type, or may be undoped. Suitable gallium-nitride materials are described in U.S. Pat. No. 6,649,287, which is incorporated herein by reference in its entirety.

For some semiconductor applications, heteroepitaxy may involve crystalline materials with similar material properties (e.g., nearly similar lattice constants, nearly similar thermal expansion coefficients) and may require only a thin layer of heteroepitaxial growth. However, the inventors have recognized and appreciated that some semiconductor applications can require a substantial thickness of overgrown material (e.g., more than 2 microns) having an appreciable difference in lattice constant from the substrate. For example, the inventors have recognized and appreciated that high-performance transistors and Schottky diodes fabricated from gallium-nitride material can benefit greatly, at least in terms of breakdown voltages, with increased thicknesses of heteroepitaxial gallium-nitride layers. Reverse-breakdown voltages greater than 2000 volts have been observed for such devices when the thickness of an overgrown gallium-nitride layer and buffer is greater than about 4 microns.

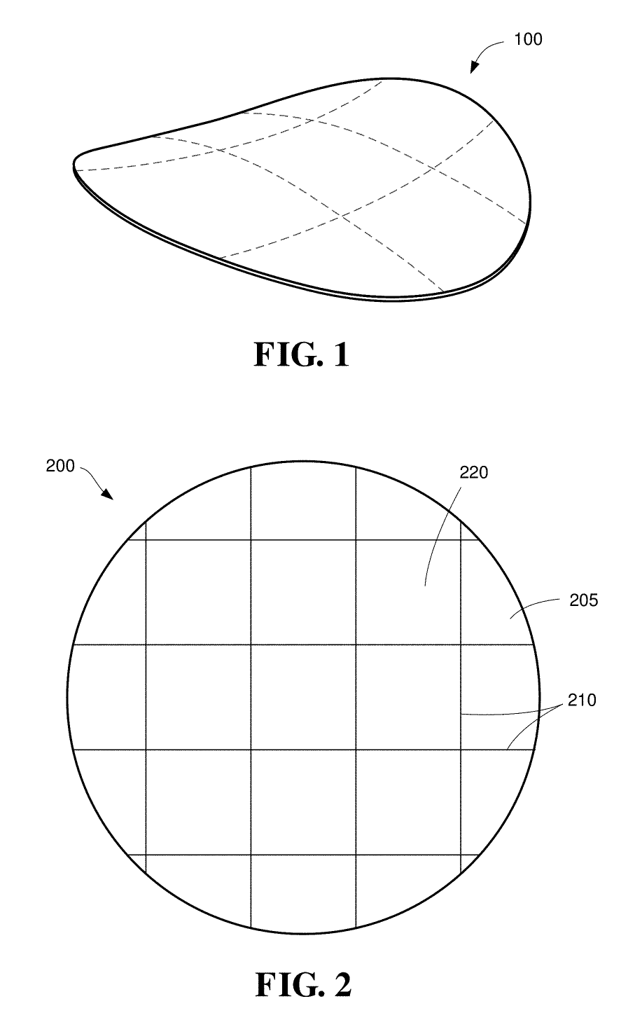

The inventors have further recognized and appreciated that when there is an appreciable difference in material properties (lattice constants, coefficient of thermal expansion, innate stress) between a heteroepitaxial layer and underlying substrate and/or a thick heteroepitaxial layer is required, in-plane stresses that form in the heteroepitaxial layer can cause out-of-plane distortion of the entire wafer. For example, a wafer 100 may bow, as depicted in FIG. 1, though the illustration may exaggerate the amount of bending that can occur for purposes of explanation. In practice, even a small amount of warpage (e.g., less than 100 microns out of plane) can cause problems during microfabrication processes and typically must be addressed. If the in-plane stresses are high enough in the heteroepitaxial layer, defects in the crystal structure may occur at random locations and lead to low device yield or premature device failure.

The inventors have conceived of structures and methods for reducing wafer bow that can occur during heteroepitaxy. In overview and referring now to FIG. 2, a plurality of micro-trenches 210 may be formed across a surface of a substrate 205, according to some embodiments, and may or may not intersect. The substrate 205 may comprise or consist of monocrystalline material on which a heteroepitaxial layer is to be grown. The micro-trenches may be filled with a non-monocrystalline material, and the wafer planarized for subsequent heteroepitaxy. During heteroepitaxy, the regions over the micro-trenches may form as non-monocrystalline material (e.g., as polycrystalline or amorphous material) and provide in-plane stress relief for the heteroepitaxial layer. In device areas 220 between the micro-trenches, a heteroepitaxial layer of monocrystalline material may form.

Example substrates include, but are not limited to, silicon (Si), silicon carbide (SiC), gallium nitride (GaN), and sapphire. According to some embodiments, the substrate 205 may comprise bulk monocrystalline silicon. In some instances, the substrate may comprise a semiconductor on insulator (SOI) substrate where the semiconductor is any of the foregoing mentioned semiconductor substrate materials. The substrate 205 may be in the form of a semiconductor wafer (e.g., a Si semiconductor wafer) and have a diameter between approximately 50 mm and approximately 450 mm. In various embodiments, the surface of the substrate is monocrystalline, so that a III-nitride (e.g., GaN, AlN, AlGaN, InGaN) or any other suitable crystalline III-V, II-VI, tertiary, or quarternary material may be grown from the surface of the substrate.

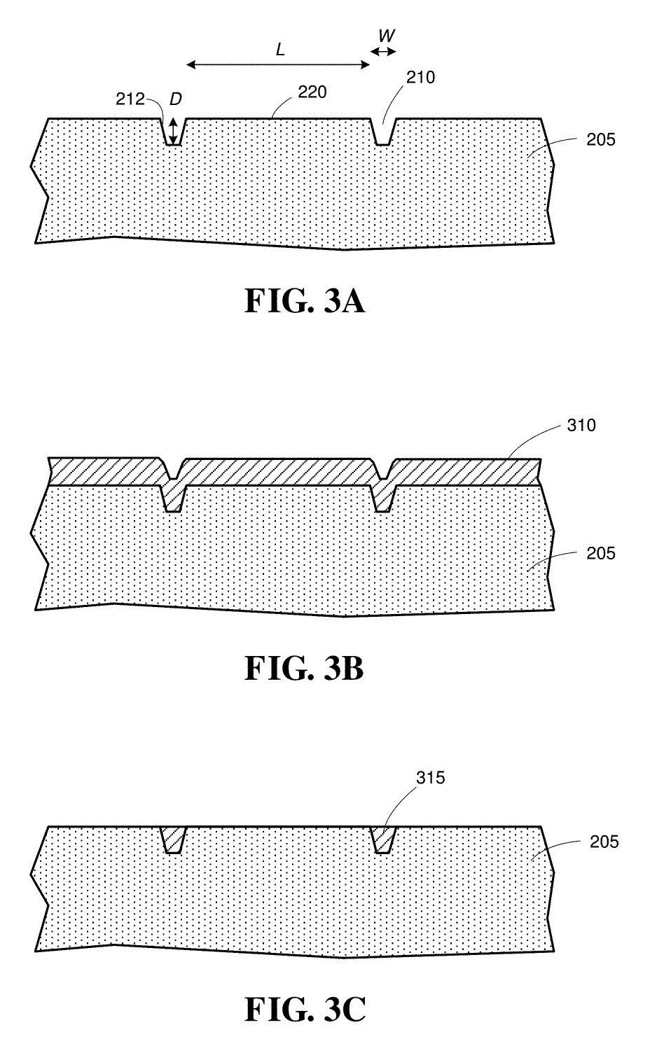

In further detail, FIG. 3A depicts a cross-sectional view of two micro-trenches 210 formed in a portion of a substrate 205. A micro-trench 210 may have a width W, a depth D, and be separated by a distance L. The width W of the micro-trenches may be between 10 μm and 100 μm, in some embodiments. In some cases, the width W of the micro-trenches may be between 1 μm and 100 μm. The depth D of the micro-trenches may be between 10 nm and 3 μm, in some embodiments. The micro-trenches 210 may be separated by a distance L between 0.5 mm and 10 mm, according to some embodiments. The micro-trenches may be arranged on a surface of the substrate 205 in any suitable pattern.

For example, in some cases the micro-trenches may be arranged in a rectangular pattern, as depicted in FIG. 2, or in a triangular pattern or hexagonal pattern. The micro-trenches 210 may be patterned on a substrate 205 in a regular pattern, as depicted in FIG. 2, or in other patterns that do not have regular periodicity. In some implementations, the micro-trenches 210 may be aligned with crystallographic planes of the substrate material or of a subsequently-grown device layer described below. In such embodiments, the pattern of micro-trenches may depend upon the cut of the substrate (e.g., depend upon whether a silicon substrate is <111>, <100>, or <110> silicon. In some cases, the micro-trenches 210 may run along die streets on the substrate 205 that define device areas 220. After microfabrication of devices in the device areas 220, the wafer 200 may be diced along the micro-trenches 210 removing all or some of the structure associated with the micro-trenches.

Referring to FIG. 3A, the micro-trenches 210 may have a trench profile 212 of any suitable shape. In some embodiments, the sidewalls of the micro-trenches may be sloped as depicted in the drawing. Such a sloped sidewall profile may be obtained, in some cases, by using a wet etch process that preferentially etches along crystallographic planes of the substrate 205. Alternatively, a weak anisotropic dry etch (e.g., reactive-ion etch) may be used to obtain a sloped trench profile 212. In other embodiments, the trench profile 212 may be dished or rounded. For example, a bowl-shaped profile may be obtained using an isotropic wet etch. In yet other embodiments, the trench profile 212 may have vertical sidewalls, which can be produced using an anisotropic dry etch, for example.

The micro-trenches 210 may be patterned using any suitable photolithographic process. For example a photoresist and/or hard mask (not shown) may be formed over the substrate 205 and patterned to expose lines across the surface of the substrate 205. Subsequently, an etching process may be used to form the micro-trenches 210 into the substrate 205. The photoresist and/or hard mask may then be stripped from the substrate.

After the micro-trenches 210 are formed, a fill material 310 may be deposited over the substrate 205, as depicted in FIG. 3B. The fill material 310 may comprise a non-monocrystalline material which may or may not have the same chemical composition as the substrate 205. Accordingly, the fill material may differ from the substrate in chemical composition and/or material properties. For example, the fill material may comprise amorphous or polycrystalline silicon, in some embodiments, that is deposited over monocrystalline silicon substrate 205 using any suitable deposition process (sputtering, electron-beam evaporation, chemical vapor deposition, plasma-enhanced chemical vapor deposition, etc.). The deposition process for the fill material may not form monocrystalline material in the micro-trenches. According to some embodiments, the fill material 310 is deposited to a thickness that is greater than the depth D of the micro-trenches 210 at the trenches.

Materials other than silicon may be used to fill the micro-trenches 210 in other embodiments. Fill material 310 may include, but not be limited to silicon-carbide, silicon-nitride, silicon-germanium, gallium-nitride materials, aluminum-nitride, indium-phosphide. In various embodiments, the fill material 310 is capable of withstanding temperatures for epitaxy and/or subsequent device fabrication, and allows heteroepitaxial growth of a desired semiconductor layer (e.g., gallium-nitride, gallium-arsenide, indium-phosphide, etc.) over the fill material. For example, the fill material may remain amorphous or polycrystalline for epitaxy and/or anneal temperatures up to 600° C., according to some embodiments.

A planarization process may then be used to planarize the wafer, as depicted in FIG. 3C. In some implementations, diamond grinding of the wafer surface may be performed to remove at least a portion of the fill material 310. In some cases, chemical mechanical polishing (CMP) may be used to remove at least a portion of the fill material and/or provide a wafer surface suitable for crystal overgrowth above the device areas 220. For example, the fill material 310 may be removed completely over the device areas 220 to expose the underlying monocrystalline substrate 205. The resulting substrate surface may comprise a plurality of filled micro-trenches 315 distributed across the wafer, wherein a non-monocrystalline material fills the micro-trenches. In some implementations, the fill material 310 that remains in the micro-trenches 210 may getter impurities from a subsequently formed device layer and/or buffer.

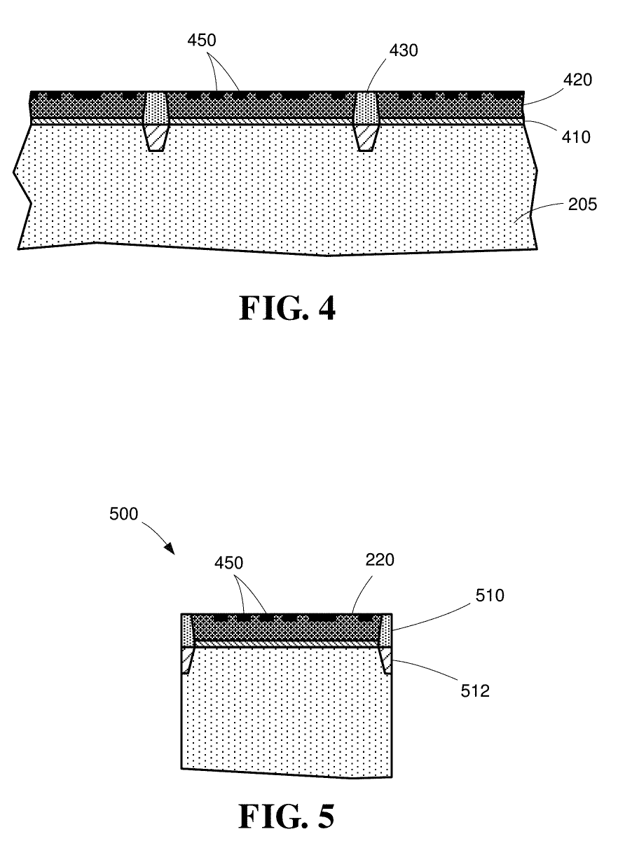

A heteroepitaxy process may be carried out on the wafer, as depicted in FIG. 4, to form a desired semiconductor device layer 420 for device fabrication. In some cases, a buffer 410 may be formed over the substrate 205 prior to forming the device layer 420. The buffer 410 may comprise one or more transitional layers of material between the substrate 205 and the desired device layer 420, in which semiconductor devices 450 for integrated circuit applications may be fabricated. Examples of buffers and transitional layers are described in, for example, U.S. Pat. No. 7,135,720 and U.S. Pat. No. 9,064,775, which are both incorporated herein by reference in their entirety. Some of the transitional layers may be compositionally graded. The buffer 410 and/or device layer 420 may be formed by any suitable crystal-growth process including, but not limited to metal-organic chemical vapor deposition (MOCVD), molecular beam epitaxy (MBE), hydride vapor phase epitaxy (HVPE), atomic layer deposition (ALD) or a combination thereof. A thickness of the device layer 420 may be between 1 micron and 6 microns, in some embodiments. In other embodiments, the device layer may have a thickness less than or greater than this range.

As just one example, a substrate 205 may comprise silicon or silicon carbide, and the buffer may comprise aluminum-nitride and/or aluminum-gallium-nitride compositions. The device layer 420 may then comprise a gallium-nitride material. Other buffers and device layers may be used in other embodiments.

According to some embodiments, the buffer 410 and/or the device layer 420 may form as monocrystalline structures over the device areas 220 since they can register to the underlying monocrystalline material of the substrate 205. However, in regions over the micro-trenches 210 that are filled with non-monocrystalline material, non-monocrystalline trench-overgrowth regions 430 may form. In the trench-overgrowth regions 430, the material may be different (at least in terms of material properties) from the material of the device layer 420 within the device areas 220. For example, the material of the device layer and/or the buffer may be amorphous or polycrystalline in the trench-overgrowth regions 430 whereas the corresponding material(s) may be monocrystalline in the device areas 220. Because of their non-monocrystalline material property, the trench-overgrowth regions 430 may relieve in-plane stress (compressive or tensile) in the device layer 420, and may relieve in-plane stresses at the surface of the substrate 205. The relief of in-plane stresses can reduce wafer bow and reduce defect formation in the device areas 220.

Since the fill material 310 in the micro-trenches 210 only need disrupt monocrystalline formation of the device layer 420 in the trench-overgrowth regions 430, the depth D of the micro-trenches 210 may be shallow in some cases. For example, the micro-trenches may have a depth between 10 nm and 100 nm, in some embodiments.

After growth of the device layer 420, microfabrication of integrated-circuit devices 450 may be carried out using conventional semiconductor processing techniques, modified to accommodate the micro-trenches 210 and trench-overgrowth regions 430. In these regions, devices may not be formed to avoid potentially high defect concentrations or inadequate device performance. After microfabrication of devices 450, the wafer may be diced by diamond sawing, for example, to form a plurality of die 500. A depiction of one die is shown in FIG. 5. According to some embodiments, the wafer may be diced along the micro-trenches 210 and fill remnants 512 and non-monocrystalline, trench-overgrowth remnants 510 may remain at or near a periphery of the die. In some implementations, a die 500 may span more than one device area 220, so that one or more trench-overgrowth regions 430 and filled micro-trenches 315 are located within a die. According to some embodiments, the trench-overgrowth regions 430 and/or filled micro-trenches 315 may be used for electrical isolation between devices on a die 500.

When using the terms “on,” “adjacent,” or “over” in to describe the locations of layers or structures, there may or may not be one or more layers of material between the described layer and an underlying layer that the layer is described as being on, adjacent to, or over. When a layer is described as being “directly” or “immediately” on, adjacent to, or over another layer, no intervening layer is present. When a layer is described as being “on” or “over” another layer or substrate, it may cover the entire layer or substrate, or a portion of the layer or substrate. The terms “on” and “over” are used for ease of explanation relative to the illustrations, and are not intended as absolute directional references. A device may be manufactured and/or implemented in other orientations than shown in the drawing (for example, rotated about a horizontal axis by more than 90 degrees.

### CONCLUSION

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

The technology described herein may be embodied as a method, of which at least some acts have been described. The acts performed as part of the method may be ordered in any suitable way. Accordingly, embodiments may be constructed in which acts are performed in an order different than described, which may include performing some acts simultaneously, even though described as sequential acts in illustrative embodiments. Additionally, a method may include more acts than those described, in some embodiments, and fewer acts than those described in other embodiments.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. A semiconductor wafer comprising:
a substrate formed of a first material;
a layer of a second material different from the first material formed over the first material;
a plurality of micro-trenches formed in a surface of the substrate that faces the layer of the second material;
a third material different from the first material located in the plurality of micro-trenches;
a fourth material different from the second material located in regions above the third material in the layer of the second material that relieves in-plane stress in the layer of second material; and
a planar buffer layer extending between the substrate and the layer of the second material and between the third material and the fourth material.

2. The semiconductor wafer of claim 1, wherein the second material is a monocrystalline gallium-nitride material and the fourth material is polycrystalline or amorphous gallium-nitride material.

3. The semiconductor wafer of claim 2, wherein a thickness of the layer of the second material layer is between 1 micron and 6 microns.

4. The semiconductor wafer of claim 1, wherein the planar buffer layer extending between the third material and the fourth material is amorphous or polycrystalline.

5. The semiconductor wafer of claim 1, wherein the plurality of micro-trenches are distributed across an entire surface of the substrate in a regular pattern that includes intersecting micro-trenches.

6. The semiconductor wafer of claim 1, wherein the plurality of micro-trenches are distributed across an entire surface of the substrate in die streets.

7. The semiconductor wafer of claim 1, wherein device areas are located in regions between the plurality micro-trenches and span a distance between 0.5 mm and 10 mm.

8. The semiconductor wafer of claim 1, further comprising integrated circuit devices formed in device areas that are located between the plurality of micro-trenches.

9. The semiconductor wafer of claim 1, wherein the plurality of micro-trenches have a cross-sectional profile with non-vertical sidewalls.

10. The semiconductor wafer of claim 1, wherein the plurality of micro-trenches have a width between 1 micron and 100 microns.

11. The semiconductor wafer of claim 1, wherein the substrate comprises silicon, silicon-carbide, or sapphire.

12. A semiconductor die comprising:
a substrate formed of a first material;
a layer of a second material different from the first material formed over the first material;
an integrated circuit device formed in the layer of the second material;
a micro-trench or portion thereof formed in a surface of the substrate that faces the layer of the second material;
a third material different from the first material located in the micro-trench or portion thereof;
a fourth material different from the second material located in a region above the third material in the layer of the second material that relieves in-plane stress in the layer of second material; and
a planar buffer layer extending between the substrate and the layer of the second material and between the third material and the fourth material.

13. The semiconductor die of claim 12, wherein the second material is a monocrystalline gallium-nitride material and the fourth material is polycrystalline or amorphous gallium-nitride material.

14. The semiconductor die of claim 13, wherein a thickness of the second layer is between 1 micron and 6 microns.

15. The semiconductor die of claim 12, wherein the planar buffer layer extending between the third material and the fourth material is amorphous or polycrystalline.

16. The semiconductor die of claim 12, wherein the micro-trench or portion thereof is located at a periphery of the die.

17. The semiconductor die of claim 12, wherein the substrate comprises silicon, silicon-carbide, or sapphire.

18. A method for reducing bow during semiconductor heteroepitaxial growth, the method comprising:
forming a plurality of micro-trenches in a surface of a substrate comprising a first material;
depositing a second material different from the first material over the substrate and the plurality of micro-trenches;
performing a planarization process that removes a portion of the second material;
epitaxially growing a layer of third material different from the first material over the substrate; and
forming regions of fourth material different from the third material in the layer of third material over the micro-trenches, wherein the fourth material relieves in-plane stress in the layer of third material.

19. The method of claim 18, wherein the third material is a monocrystalline gallium-nitride material and the fourth material is polycrystalline or amorphous gallium-nitride material.

20. The method of claim 18, wherein the third material and the fourth material are formed at a same time.

21. The method of claim 18, further comprising forming the plurality of micro-trenches in die streets.

22. The method of claim 18, further comprising dicing the substrate along the micro-trenches to remove all or a portion of the micro-trenches.

23. The method of claim 18, further comprising forming a buffer between the substrate and the layer of third material.

24. The method of claim 18, wherein the layer of third material is grown to a thickness between 1 micron and 6 microns.

25. The method of claim 18, further comprising forming an integrated circuit device in the layer of third material.
